(19) United States
(12) Patent Application Publication
(10) Pub. No.: US 2024/0313073 A1
(43) Pub. Date: Sep. 19, 2024

(54) SEMICONDUCTOR MEMORY DEVICE AND MANUFACTURING METHOD OF SEMICONDUCTOR MEMORY DEVICE

(71) Applicant: SK hynix Inc., Icheon-si Gyeonggi-do (KR)

(72) Inventors: Jae Hyun HAN, Icheon-si Gyeonggi-do (KR); Won Tae KOO, Icheon-si Gyeonggi-do (KR)

(73) Assignee: SK hynix Inc., Icheon-si Gyeonggi-do (KR)

(21) Appl. No.: 18/675,467

(22) Filed: May 28, 2024

Related U.S. Application Data
(62) Division of application No. 17/483,215, filed on Sep. 23, 2021.

(30) Foreign Application Priority Data
Apr. 5, 2021 (KR) 10-2021-0044294

(51) Int. Cl. H01L 29/423; H01L 21/28; H10B 41/27; H10B 43/27

(52) U.S. Cl. CPC H01L 29/42332; H01L 29/40114; H01L 29/40117; H01L 29/42348; H10B 41/27; H10B 43/27

(57) ABSTRACT

A semiconductor memory device includes a channel layer, a gate electrode spaced apart from the channel layer, a blocking insulating layer between the gate electrode and the channel layer, a tunnel insulating layer between the channel layer and the blocking insulating layer, and nano-particles spaced apart from each other between the tunnel insulating layer and the blocking insulating layer.

### CROSS-REFERENCE TO RELATED APPLICATION

The present application is a divisional application of U.S. patent application Ser. No. 17/483,215, filed on Sep. 23, 2021, which claims priority under 35 U.S.C. § 119(a) to Korean patent application number 10-2021-0044294, filed on Apr. 5, 2021, in the Korean Intellectual Property Office, the entire contents of which applications are incorporated herein by reference.

### BACKGROUND

### 1. Technical Field

The present disclosure generally relates to a semiconductor

memory device and a manufacturing method of the semiconductor memory device, and more particularly, to a nonvolatile memory device and a manufacturing method of the nonvolatile memory device.

### 2. Related Art

A nonvolatile memory device may retain data even when a supply of power is interrupted. A flash memory device is a type of nonvolatile memory device, and it is used for various portable electronic devices.

A data storage layer of the flash memory device may be made of various materials. When a floating gate made of poly-silicon is used as the data storage layer, electrical characteristics of a cell may be improved. When a charge trap layer made of a nitride layer is used as the data storage layer, a manufacturing process of the data storage layer may be simplified.

As described above, a semiconductor memory device to which various materials are applied as the data storage layer has been developed, and various techniques for improving the operational reliability of the semiconductor memory device have been developed.

### SUMMARY

In accordance with an embodiment of the present disclosure, a semiconductor memory device includes a channel layer, a gate electrode spaced apart from the channel layer, a blocking insulating layer between the gate electrode and the channel layer, a tunnel insulating layer between the channel layer and the blocking insulating layer, and a data storage layer between the tunnel insulating layer and the blocking insulating layer. The data storage layer includes nano-particles spaced apart from each other by a porous structure, a chemical chain or a gap.

In accordance with an embodiment of the present disclosure, a semiconductor memory device includes a channel layer, a gate electrode spaced apart from the channel layer, a blocking insulating layer between the gate electrode and the channel layer, nano-particles spaced apart from each other between the blocking insulating layer and the channel layer, a tunnel insulating layer disposed between the blocking insulating layer and the channel layer, and an insulating layer between the nano-particles.

In accordance with an embodiment of the present disclosure, a method of manufacturing a semiconductor memory device includes forming a stack structure including first material layers and second material layers, which are alternately stacked, forming a hole penetrating the stack structure, forming a blocking insulating layer on a sidewall of the hole, forming a data storage layer having nano-particles spaced apart from each other by a porous structure or a chemical chain on the blocking insulating layer, forming a tunnel insulating layer on the data storage layer, and forming a channel layer on the tunnel insulating layer.

### BRIEF DESCRIPTION OF THE DRAWINGS

Example embodiments will now be described more fully hereinafter with reference to the accompanying drawings; however, they may be embodied in different forms and should not be construed as being limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it may be the only element between the two elements, or additional intervening elements may also be present. Like reference numerals refer to like elements throughout the drawings.

FIG. 1 is a schematic circuit diagram illustrating a semiconductor memory device in accordance with an embodiment of the present disclosure.

FIGS. 2A and 2B are views illustrating a three-dimensional semiconductor memory device in accordance with an embodiment of the present disclosure.

FIG. 3 is a sectional view illustrating a memory layer in accordance with an embodiment of the present disclosure.

FIGS. 4A and 4B are views illustrating a three-dimensional semiconductor memory device in accordance with an embodiment of the present disclosure.

FIGS. 5 and 6 are sectional views illustrating memory layers in accordance with embodiments of the present disclosure.

FIGS. 7A, 7B, and 7C are views illustrating nano-particles in accordance with embodiments of the present disclosure.

FIGS. 8A and 8B are flowcharts illustrating a manufacturing

method of a three-dimensional semiconductor memory device in accordance with an embodiment of the present disclosure.

FIGS. 9A and 9B are flowcharts illustrating the step of forming a memory layer shown in FIGS. 8A and 8B.

FIGS. 10A and 10B are flowcharts illustrating a manufacturing method of a memory layer using a Metal Organic Framework (MOF).

FIGS. 11A and 11B are views schematically illustrating an MOF.

FIGS. 12A and 12B are flowcharts illustrating a manufacturing method of a memory layer using a Self-Assembled Monolayer (SAM).

FIG. 13 is a block diagram illustrating a configuration of a memory system in accordance with an embodiment of the present disclosure.

FIG. 14 is a block diagram illustrating a configuration of a computing system in accordance with an embodiment of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

Some embodiments are directed to a semiconductor memory device having improved operational reliability and a manufacturing method of the semiconductor memory device.

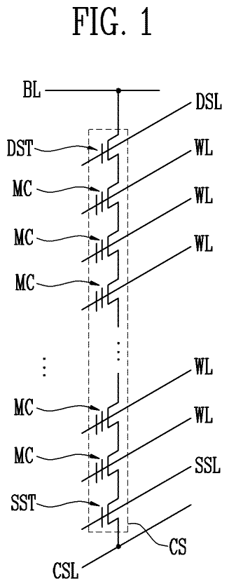

FIG. 1 is a schematic circuit diagram illustrating a semiconductor memory device in accordance with an embodiment of the present disclosure.

Referring to FIG. 1, the semiconductor memory device may be a nonvolatile memory device. In an embodiment, the semiconductor memory device may be a NAND flash memory device. The NAND flash memory device may be implemented two-dimensionally or three-dimensionally. Hereinafter, an embodiment of a three-dimensional NAND flash memory device will be illustrated and described, but the present disclosure is not limited thereto.

The NAND flash memory device may include a memory cell string CS connected to a bit line BL and a common source line CSL. The drawing illustrates one memory cell string CS, but a plurality of memory cell strings may be connected in parallel between the bit line BL and the common source line CSL.

The memory cell string CS may include a source select transistor SST, a plurality of memory cells MC, and a drain select transistor DST, which are disposed between the common source line CSL and the bit line BL.

The source select transistor SST may control an electrical connection between the plurality of memory cells MC and the common source line CSL. One source select transistor SST may be disposed between the common source line CSL and the plurality of memory cells MC. However, embodiments of the present disclosure are not limited thereto, and two or more source select transistors connected in series may be disposed between the common source line CSL and the plurality of memory cells MC. The source select transistor SST may be connected to a source select line SSL. An operation of the source select transistor SST may be controlled by a source gate signal applied to the source select line SSL.

The plurality of memory cells MC may be disposed between the source select transistor SST and the drain select transistor DST. The memory cells MC between the source select transistor SST and the drain select transistor DST may be connected in series to each other. The memory cells MC may be respectively connected to word lines WL. Operation of the memory cells MC may be controlled by cell gate signals applied to the word lines WL.

The drain select transistor DST may control an electrical connection between the plurality of memory cells MC and the bit line BL. One drain select transistor DST may be disposed between the bit line BL and the plurality of memory cells MC. However, embodiments of the present disclosure are not limited thereto, and two or more drain select transistors connected in series may be disposed between the bit line BL and the plurality of memory cells MC. The drain select transistor DST may be connected to a drain select line DSL. Operation of the drain select transistor DST may be controlled by a drain gate signal applied to the drain select line DSL.

Each memory cell MC may store single-bit data or multi-bit data.

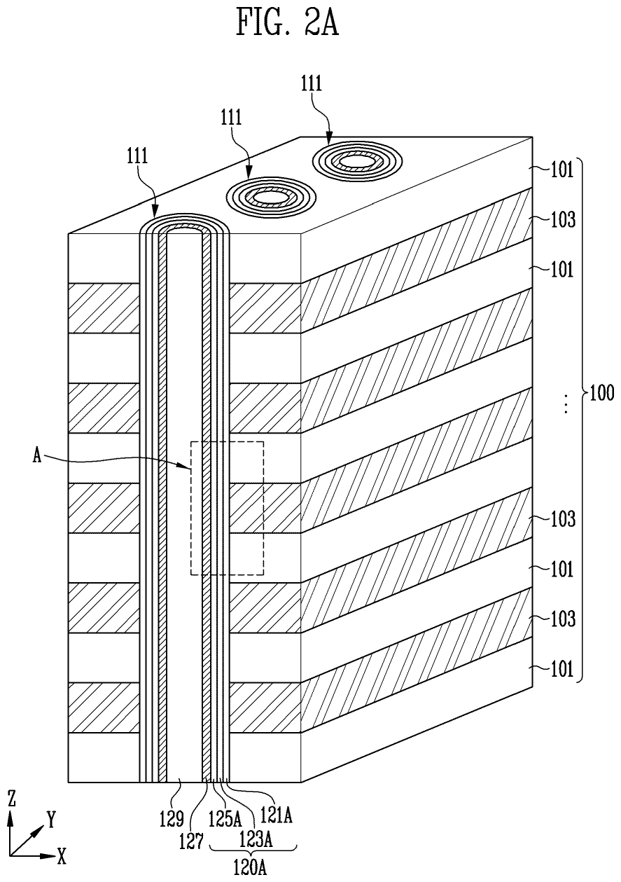

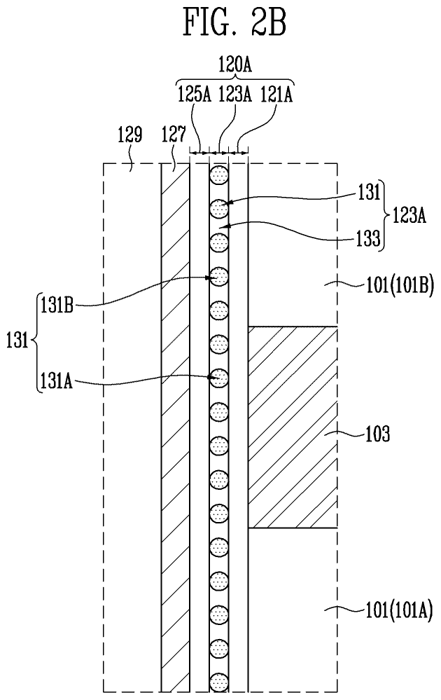

FIGS. 2A and 2B are views illustrating a three-dimensional semiconductor memory device in accordance with an embodiment of the present disclosure. FIG. 2A is a perspective view illustrating a portion the three-dimensional semiconductor memory device, and FIG. 2B is an enlarged sectional view of region A shown in FIG. 2A.

Referring to FIGS. 2A and 2B, the three-dimensional semiconductor memory device may include a channel layer 127, a memory layer 120A surrounding the channel layer 127, and a stack structure 100 surrounding the memory layer 120A.

The stack structure 100 may include interlayer insulating layers 101 and gate electrodes 103, which extend parallel to each other on an X-Y plane. The gate electrodes 103 may be used as the word lines WL shown in FIG. 1. The gate electrodes 103 may be alternately stacked with the interlayer insulating layers 101 in a Z-axis direction. Accordingly, the gate electrodes 103 may be insulated from each other by the interlayer insulating layers 101. The gate electrodes 103 may include various conductive materials such as a doped semiconductor, metal, metal nitride, and metal silicide. The interlayer insulating layers 101 may include an insulating material such as a silicon oxide layer.

The stack structure 100 may be penetrated by a hole 111 extending in the Z-axis direction. The channel layer 127 and the memory layer 120A may be formed in the hole 111.

The channel layer 127 may extend in the Z-axis direction. In an embodiment, the channel layer 127 may be formed in a pillar shape. In another embodiment, the channel layer 127 may be formed in a tubular shape having a central region filled with a core insulating layer 129. The channel layer 127 may include a semiconductor material such as silicon. The channel layer 127 may be used as a channel region of the memory cell string CS shown in FIG. 1. The channel layer 127 may extend along sidewalls of the interlayer insulating layers 101 and the gate electrodes 103. In other words, each of the interlayer insulating layers 101 and the gate electrodes 103 may surround the channel layer 127. Each of the interlayer insulating layers 101 and the gate electrodes 103 may be spaced apart from the channel layer 127 by the memory layer 120A.

The memory layer 120A may be interposed between the stack structure 100 and the channel layer 127. The memory layer 120A may include a blocking insulating layer 121A between the stack structure 100 and the channel layer 127, a tunnel insulating layer 125A between the channel layer 127 and the blocking insulating layer 121A, and a data storage layer 123A between the tunnel insulating layer 125A and the blocking insulating layer 121A. Each of the blocking insulating layer 121A, the tunnel insulating layer 125A, and the data storage layer 123A may extend along the sidewalls of the interlayer insulating layers 101 and the gate electrodes 103, and surround the channel layer 127.

As shown in FIG. 2B, the interlayer insulating layers 101 may include a first interlayer insulating layer 101A and a second interlayer insulating layer 101B, which are adjacent to each other in the Z-axis direction. A gate electrode 103 may be disposed between the first interlayer insulating layer 101A and the second interlayer insulating layer 101B. The first interlayer insulating layer 101A may be disposed under the gate electrode 103, and the second interlayer insulating layer 101B may be disposed on the gate electrode 103.

Referring to FIG. 2B, a portion of the data storage layer 123A between the gate electrode 103 and the channel layer 127 may be defined as a data storage region, and another portion of the data storage layer 123A between each of the interlayer insulating layers 101 and the channel layer 127 may be defined as a space region. The semiconductor memory device may control the quantity of charges stored in the data storage region according to a signal applied to the gate electrode 103.

The data storage layer 123A may include nano-particles 131. The nano-particles 131 may have a size of 10 nanometers or less. The nano-particles 131 may be metal nano-particles or be silicon nano-particles. The nano-particles 131 may be spaced apart from each other with a space 133 interposed therebetween. The space 133 may be caused by a porous structure, a chemical chain or a gap (e.g., an air-gap). The nano-particles 131 may be divided into cell nano-particles 131A distributed between the gate electrode 103 and the tunnel insulating layer 125A, and dummy nano-particles 131B distributed between each of the interlayer insulating layers 101 and the tunnel insulating layer 125A. The nano-particles 131 may be substantially formed in a spherical shape. When the nano-particles 131 are formed in the spherical shape, an electric field applied between the gate electrode 103 and the channel layer 127 may be concentrated on the cell nano-particles 131A, during a program operation or an erase operation.

The blocking insulating layer 121A may include a single layer or a multi-layer. The blocking insulating layer 121A may include an oxide.

The tunnel insulating layer 125A may include an insulating material such as a silicon oxide layer, through which tunneling is possible.

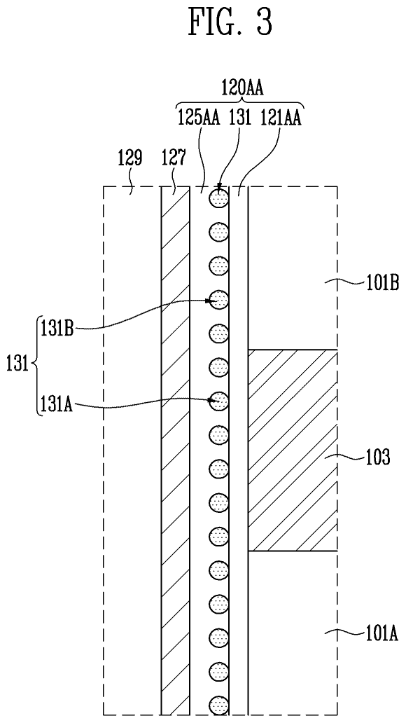

FIG. 3 is a sectional view illustrating a memory layer in accordance with an embodiment of the present disclosure. FIG. 3 is an enlarged sectional view of a partial region of the semiconductor memory device, which corresponds to region A shown in FIG. 2A. Hereinafter, repeated descriptions of portions overlapping with those shown in FIGS. 2A and 2B will be omitted.

Referring to FIG. 3, the memory layer 120AA may be interposed between the gate electrode 103 and the channel layer 127. The channel layer 127 may be formed in a tubular shape having a central region filled with the core insulating layer 129 as described with reference to FIG. 2A. The memory layer 120AA may include a blocking insulating layer 121AA between the gate electrode 103 and the channel layer 127, nano-particles 131 spaced apart from each other between the channel layer 127 and the blocking insulating layer 121AA, and a tunnel insulating layer 125AA between the blocking insulating layer 121AA and the channel layer 127.

Each of the channel layer 127, the blocking insulating layer 121AA, and the tunnel insulating layer 125AA may extend along the sidewalls of the first interlayer insulating layer 101A and the second interlayer insulating layer 101B. The blocking insulating layer 121AA may include an oxide. The tunnel insulating layer 125AA may include an insulating material such as a silicon oxide layer, through which tunneling is possible. The tunnel insulating layer 125AA may extend between the nano-particles 131. The nano-particles 131 may be divided into cell nano-particles 131A distributed between the gate electrode 103 and the channel layer 127, and dummy nano-particles 131B distributed between each of the first and second interlayer insulating layers 101A and 101B and the channel layer 127.

The semiconductor memory device may control the quantity of charges stored in the cell nano-particles 131A according to a signal applied to the gate electrode 103.

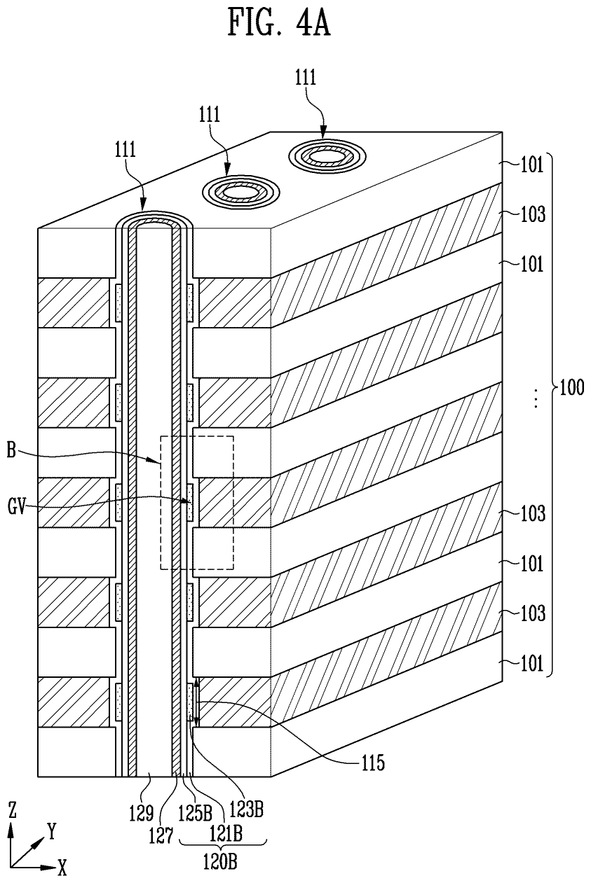

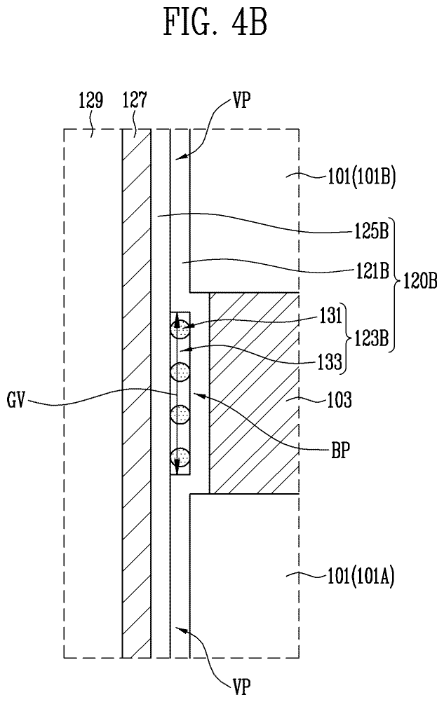

FIGS. 4A and 4B are views illustrating a three-dimensional semiconductor memory device in accordance with an embodiment of the present disclosure. FIG. 4A is a perspective view illustrating a portion of the three-dimensional semiconductor memory device, and FIG. 4B is an enlarged sectional view of region B shown in FIG. 4A.

Referring to FIGS. 4A and 4B, the three-dimensional semiconductor memory device may include a channel layer 127, a memory layer 120B surrounding the channel layer 127, and a stack structure 100 surrounding to the memory layer 120B.

Interlayer insulating layers 101 and gate electrodes 103 of the stack structure 100 may be penetrated by a hole 111 extending in the Z-axis direction. The channel layer 127 may extend in the Z-axis direction in the hole 111. A central region of the hole 111 may be filled with a core insulating layer 129.

The interlayer insulating layers 101 may protrude farther toward the channel layer 127 than the gate electrodes 103. Accordingly, a recess region 115 may be defined between the interlayer insulating layers 101 adjacent to each other in the Z-axis direction.

The memory layer 120B may include a blocking insulating layer 121B between the stack structure 100 and the channel layer 127, a tunnel insulating layer 125B between the channel layer 127 and the blocking insulating layer 121B, and a data storage layer 123B between the tunnel insulating layer 125B and the blocking insulating layer 121B.

A portion of the memory layer 120B may be disposed in the hole 111, and another portion of the memory layer 120B may be disposed in the recess region 115. In an embodiment, a portion of the blocking insulating layer 121B between each of the gate electrodes 103 and the channel layer 127 may be disposed in the recess region 115, and another portion of the blocking insulating layer 121B between each of the interlayer insulating layers 101 and the channel layer 127 may be disposed in the hole 111.

As shown in FIG. 4B, a first interlayer insulating layer 101A and a second interlayer insulating layer 101B may protrude farther toward the channel layer 127 than the gate electrode 103. Accordingly, the recess region 115 shown in FIG. 4A may be defined between the first interlayer insulating layer 101A and the second interlayer insulating layer 101B.

Referring to FIG. 4B, each of the channel layer 127 and the tunnel insulating layer 125B may extend along sidewalls of the first interlayer insulating layer 101A and the second interlayer insulating layer 101B.

The blocking insulating layer 121B may be formed along an uneven surface defined by a sidewall of the gate electrode 103, a protrusion part of the first interlayer insulating layer 101A, and a protrusion part of the second interlayer insulating layer 101B. For example, the blocking insulating layer 121B may include a bending part BP and vertical parts VP extending from the bending part BP. The bending part BP may be disposed between the tunnel insulating layer 125B and the gate electrode 103. The bending part BP may be conformally formed along the sidewall of the gate electrode 103, a partial top surface of the first interlayer insulating layer 101A, and a partial bottom surface of the second interlayer insulating layer 101B, and have a concave groove GV. The vertical parts VP may respectively extend between the first interlayer insulating layer 101A and the tunnel insulating layer 125B and between the second interlayer insulating layer 101B and the tunnel insulating layer 125B from the bending part BP. The vertical parts VP may be in contact with the tunnel insulating layer 125B.

The data storage layer 123B may fill the groove GV defined in the bending part BP of the blocking insulating layer 121B, and be disposed between the vertical parts VP. At levels where the interlayer insulating layers 101 are disposed, the vertical parts VP of the blocking insulating layer 121B are in contact with the tunnel insulating layer 125B, and hence the data storage layer 123B may be cut at the levels where the interlayer insulating layers 101 are disposed.

The data storage layer 123B may include nano-particles spaced

apart from each other with a space 133 caused by a porous structure, a chemical chain or a gap, which is interposed therebetween.

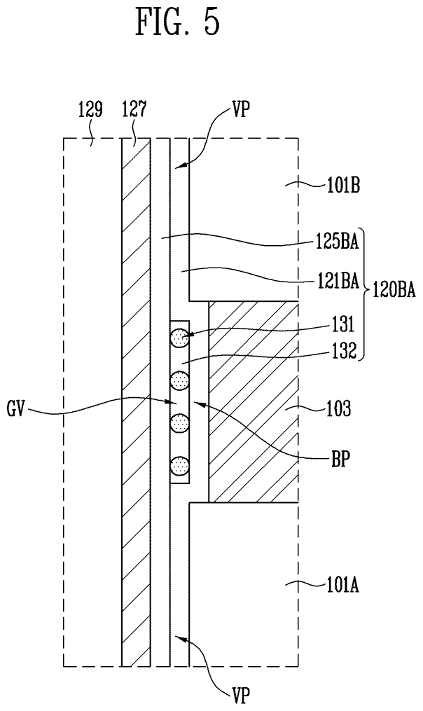

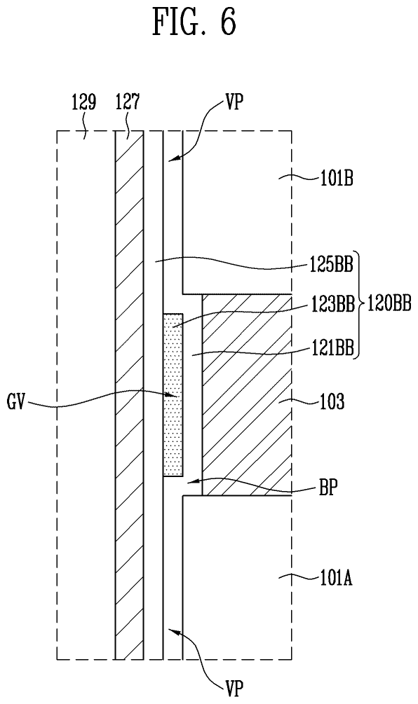

FIGS. 5 and 6 are sectional views illustrating memory layers in accordance with embodiments of the present disclosure. FIGS. 5 and 6 are enlarged sectional views of a partial region of the semiconductor memory device, which corresponds to the region B shown in FIG. 4A, and illustrate other embodiments of the above-described memory layer. Hereinafter, repeated descriptions of portions overlapping with those shown in FIGS. 2A, 2B, 4A, and 4B will be omitted.

Referring to FIGS. 5 and 6, the memory layer 120BA or 120BB may be interposed between the gate electrode 103 and the channel layer 127. The channel layer 127 may be formed in a tubular shape having a central region filled with the core insulating layer 129 as described with reference to FIG. 2A.

The memory layer 120BA or 120BB may extend between each of the first interlayer insulating layer 101A and the second interlayer insulating layer 101B, and the channel layer 127 from between the gate electrode 103 and the channel layer 127. A blocking insulating layer 121BA or 121BB of the memory layer 120BA or 120BB may include vertical parts

VP and a bending part BP. The vertical parts VP of the blocking insulating layer 121BA or 121BB may be in contact with a tunnel insulating layer 125BA or 125BB at levels where the first interlayer insulating layer 101A and the second interlayer insulating layer 101B are disposed.

The memory layer 120BA or 120BB may include nano-particles 131 spaced apart from each other as shown in FIG. 5, or include a floating gate pattern 123BB defined by an aggregation of nano-particles as shown in FIG. 6.

Referring to FIG. 5, the memory layer 120BA may further include an insulating layer 132 between the tunnel insulating layer 125BA and the bending part BP of the blocking insulating layer 121BA. The insulating layer 132 may extend between the nano-particles 131. The nano-particles 131 may be disposed between the vertical parts VP of the blocking insulating layer 121BA, and be spaced apart from each other in a groove GV defined by the bending part BP of the blocking insulating layer 121BA.

Referring to FIG. 6, the floating gate pattern 123BB may be disposed between the vertical parts VP of the blocking insulating layer 121BB, and be disposed in a groove GV defined by the bending part BP of the blocking insulating layer 121BB. The floating gate pattern 123BB may include a silicon layer formed by an aggregation of silicon nano-particles. At a level where the gate electrode 103 is disposed, the tunnel insulating layer 125BB may be spaced apart from the bending part BP of the blocking insulating layer 121BB by the floating gate pattern 123BB.

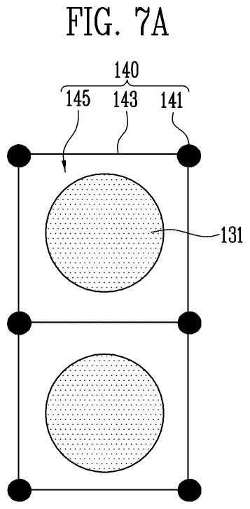

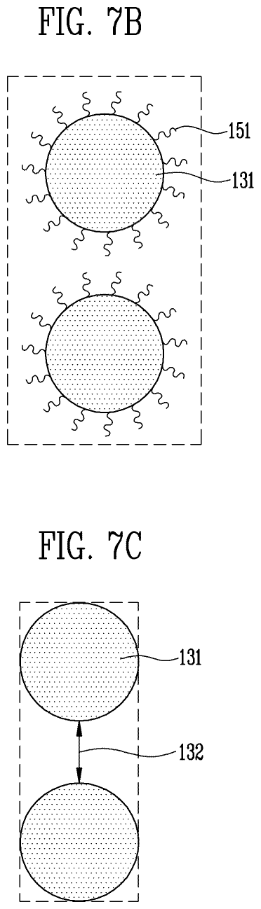

FIGS. 7A, 7B, and 7C are views illustrating nano-particles in accordance with embodiments of the present disclosure.

FIGS. 7A and 7B are views illustrating nano-particles spaced apart from each other, and may correspond to the nano-particles 131 shown in FIGS. 2B and 4B.

Referring to FIG. 7A, the nano-particles 131 may be spaced apart from each other at a constant distance by a Metal Organic Framework (MOF) 140 having a porous structure. The MOF 140 is a porous compound formed through chemical bonding between a metal ion or metal cluster 141 and an organic ligand 143. The MOF 140 may include pores 145 having a constant size and a constant arrangement. The nano-particles 131 are respectively disposed in the pores 145 having the constant size and the constant arrangement by the MOF 140, and thus a distance between the nano-particles 131 may be constantly maintained. The pores 145 of the MOF 140 may be two-dimensionally arranged or be three-dimensionally arranged according to the kind of the MOF 140.

Referring to FIG. 7B, a Self-Assembled Monolayer (SAM) 151 may be adsorbed on the nano-particles 131 to uniform the distance between the nano-particles 131 by the SAM having a chemical chain. The chain length of the SAM 151 is adjustable, and hence the distance between the nano-particles 131 may be constantly formed.

FIG. 7C is a view illustrating nano-particles 131 spaced apart from each other by an insulating layer, and may correspond to the nano-particles 131 shown in FIGS. 3 and 5.

Referring to FIG. 7C, a space between the nano-particles 131 may be filled with an insulating layer 132. Accordingly, a phenomenon in which charges move in the Z-axis direction shown in FIG. 2A or 2B may be reduced.

After the distance between the nano-particles 131 is adjusted through the organic ligand of the MOF or the SAM, the organic ligand of the MOF or the SAM may be removed. The insulating layer 132 fills a region in which the organic ligand of the MOF or the SAM is removed, to be disposed between the nano-particles 131.

The nano-particles 131 shown in FIGS. 7A to 7C may be metal nano-particles or be silicon nano-particles.

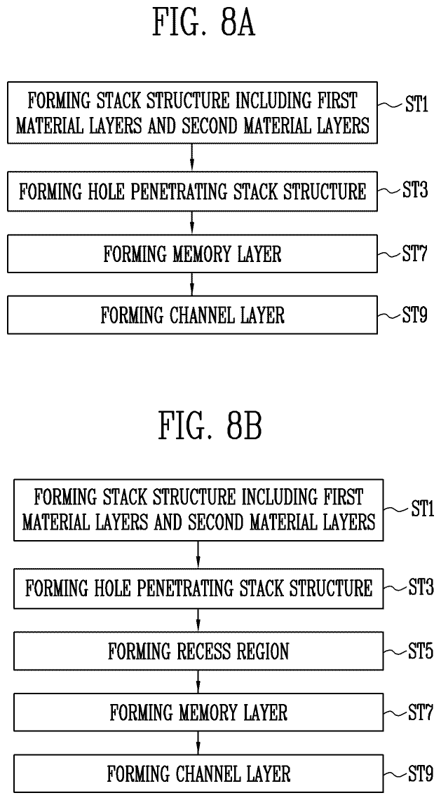

FIGS. 8A and 8B are flowcharts schematically illustrating a manufacturing method of a three-dimensional semiconductor memory device in accordance with an embodiment of the present disclosure.

Referring to FIGS. 8A and 8B, step ST1 of forming a stack structure may be performed by alternately stacking first material layers and second material layers.

In an embodiment, as shown in FIGS. 2A and 4A, each of the first material layers may include an insulating material for the interlayer insulating layer 101, and each of the second material layers may include a conductive material for the gate electrode 103. In another embodiment, the first material layers may include an insulating material for interlayer insulating layers, and the second material layers may include a sacrificial material having an etch selectivity with respect to the first material layers. For example, the first material layers may include silicon oxide, and the second material layers may include silicon nitride having an etch selectivity with respect to the silicon oxide.

Subsequently, step ST3 of forming a hole penetrating the stack structure may be performed. As shown in FIGS. 2A and 4A, the hole 111 may extend in the Z-axis direction to penetrate the stack structure 100.

After the step ST3, step ST7 of forming a memory layer may be performed.

In an embodiment, in order to provide the semiconductor memory device shown in FIGS. 2A, 2B, and 3, the step ST7 may be formed without selective etching of the second material layers, after the step ST3, as shown in FIG. 8A. Accordingly, as shown in FIG. 2A, the memory layer 120A having a substantially linear shape may be formed on a sidewall of the hole 111.

In another embodiment, in order to provide the semiconductor memory device shown in FIGS. 4A, 4B, 5, and 6, step ST5 of forming a recess region may be performed, before the step ST7 is performed, as shown in FIG. 8B. The step ST5 may be performed by selectively removing portions of the second material layers through the hole. As shown in FIG. 4A, the recess region 115 may be defined by the step ST5. When the step ST7 is performed after the step ST5, as shown in FIG. 4A, a portion of the memory layer 120B may protrude to the inside of the recess region 115, and the data storage layers 123B may be isolated from each other in the Z-axis direction.

Again, referring to FIGS. 8A and 8B, step ST9 of forming a channel layer may be performed after the step ST7. Subsequently, additional processes may be performed, such as forming a core insulating layer. When the second material layers are used as sacrificial layers, a subsequent process for replacing the second material layers with gate electrodes may be further performed.

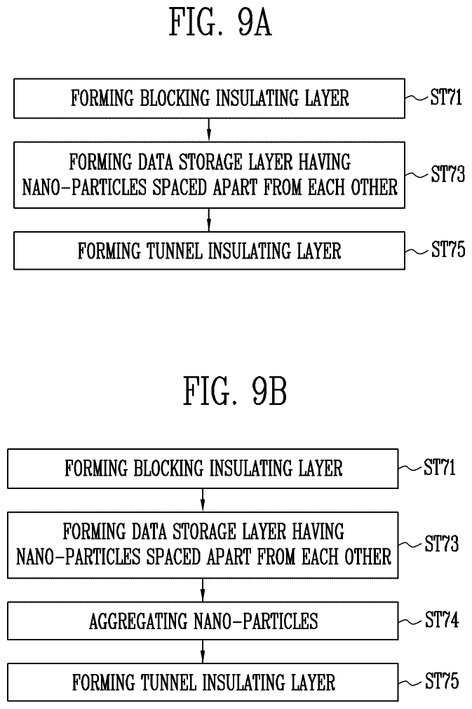

FIGS. 9A and 9B are flowcharts schematically illustrating the step ST7 shown in FIGS. 8A and 8B. An embodiment shown in FIG. 9A may be applied to the step ST7 shown in FIGS. 8A and 8B, and an embodiment shown in FIG. 9B may be applied to the step ST7 shown in FIG. 8B.

Referring to FIGS. 9A and 9B, the step ST7 may include step ST71 of forming a blocking insulating layer.

In an embodiment, the step ST71 may be performed by depositing an insulating material on the sidewall of the hole 111 as shown in FIG. 2A.

In another embodiment, the step ST71 may be performed by depositing an insulating material along surfaces of the hole 111 and the recess region 115 as shown in FIG. 4A. As shown in FIG. 4A, the blocking insulating layer 121B may be formed to have an uneven surface along the surfaces of the hole 111 and the recess region 115. For example, the blocking insulating layer 121B may have a groove GV defined at each of the levels where the second material layers (e.g., 103 shown in FIG. 4A) are disposed.

The step ST7 may include step ST73 of forming a data storage layer having nano-particles spaced apart from each other, after the step ST71.

In order to uniformly control the distance between the nano-particles, the organic ligand of the MOF 140 or the SAM 151 may be used as shown in FIGS. 7A and 7B. In an embodiment, after the distance between the nano-particles is controlled by the MOF or the SAM, a subsequent process may be performed in a state in which the MOF or the SAM remains. In an alternative embodiment, after the distance between the nano-particles is controlled by the MOF or the SAM, an organic ligand of the MOF or the SAM having a chemical chain is selectively removed.

When the step ST71 and the step ST73 are applied to the step ST7 shown in FIG. 8B, the data storage layer 123B may be disposed in the groove GV of the blocking insulating layer 121B defined at each of the levels where the second material layers (e.g., 103 shown in FIG. 4A) are disposed as shown in FIG. 4A.

The step ST7 may include step ST75 of forming a tunnel insulating layer, after the step ST73.

In an embodiment, the step ST75 may be performed in a state in which the nano-particles are spaced apart from each other as shown in

FIG. 9A. Accordingly, the nano-particles 131 in the memory layer may remain in the state in which the nano-particles 131 are spaced apart from each other as shown in FIGS. 2B, 3, 4B, and 5.

In another embodiment, as shown in FIG. 9B, a step ST74 of aggregating the nano-particles is performed before the step ST75. The step ST74 may be performed through a thermal process. As shown in FIG. 6, the floating gate pattern 123BB in which the nano-particles are fused with each other may be formed, and the tunnel insulating layer 125BB may be formed to cover the floating gate pattern 123BB.

Again, referring to FIGS. 9A and 9B, when the step ST71, the step ST73, and the step ST75 are applied to the step ST7 shown in FIG. 8B, the tunnel insulating layer 125B, 125BA, or 125BB may be in contact with the blocking insulating layer 121B, 121BA, or 121BB at each of the levels where the first material layers (e.g., 101, 101A, and 101B) are disposed as shown in FIGS. 4A, 4B, 5, and 6. In an embodiment, before the tunnel insulating layer 125BA is formed, the insulating layer 131 may be formed to fill the space between the nano-particles 132 as shown in FIG. 5.

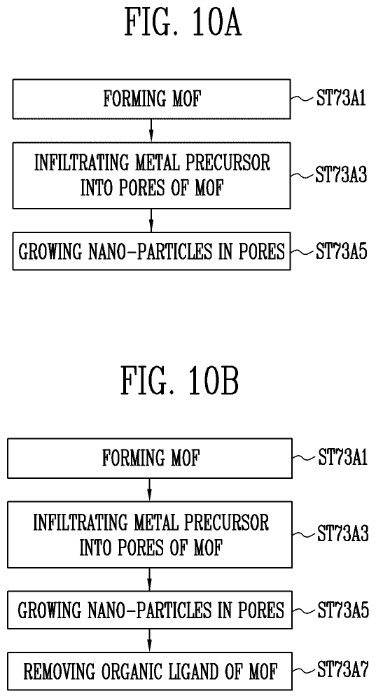

FIGS. 10A and 10B are flowcharts illustrating a manufacturing method of a memory layer using a Metal Organic Framework (MOF). Processes shown in FIGS. 10A and 10B may be applied to the step ST73 shown in FIGS. 9A and 9B.

Referring to FIGS. 10A and 10B, the step ST73 may include step ST73A1 of forming an MOF, step ST73A3 of infiltrating a metal precursor into pores of the MOF, and step ST73A5 of growing nano-particles in the pores.

In the step ST73A1, the MOF may be formed on the blocking insulating layer formed in the step ST71 shown in FIGS. 9A and 9B. As metallic salts for forming MOF, Zn₄O(CO₂)₆, Zn₃O(CO₂)₆, Cr₃O(CO₂)₆, In₃O(CO₂)₆, Ga₃O(CO₂)₆, Cu₂O(CO₂)₄, Zn₂O(CO₂)₄, Fe₂O(CO₂)₄, MO₂O(CO₂)₄, Cr₂O(CO₂)₄, Co₂O(CO₂)₄, Ru₂O(CO₂)₄, Zr₆O₄(OH₄), Zr₆O₄(CO₂)₁₂, Zr₆O₈(CO₂)₈, In(C₅HO₄N₂)₄, Na(OH)₂(SO₃)₃, Cu₂(CNS)₄, Zn(C₃H₃N₂)₄, Ni₄(C₃H₃N₂)₈, Zn₃O₃(CO₂)₃, Mg₃O₃(CO₂)₃, Ni₃O₃(CO₂)₃, Mn₃O₃(CO₂)₃, Fe₃O₃(CO₂)₃, Cu₃O₃(CO₂)₃, Al(OH)(CO₂)₂, VO(CO₂)₂, Zn(NO₃)₂, Zn(O₂CCH₃), Co(NO₃)₂, Co(O₂CCH₃), and the like may be used. As organic ligands for forming MOF, there are an oxalic acid, a fumaric acid, a terephthalic acid (H₂BDC), H₂BDC—Br, H₂BDC—OH, H₂BDC—NO₂, H₂BDC—NH₂, H₄DOT, H₂BDC—(Me)₂, H₂BDC—(Cl)₂, H₂BDC—(COOH)₂, H₂BDC—(OC₃H₅)₂, H₂BDC—(OC₇H₇)₂, H₃BTC, H₃BTE, H₃BBC, H₄ATC, H₃THBTS, H₃ImDC, H₃BTP, DTOA, H₃BTB, H₃TATB, H₄ADB, TIPA, ADP, H₆BTETCA, DCDPBN, BPP34C10DA, Ir(H₂DPBPyDC)(PPy)₂⁺, H₄DH₉PhDC, H₄DH11PhDC, H₆TPBTM, H₆BTEI, H₆BTPI, H₆BHEI, H₆BTTI, H₆PTEI, H₆TTEI, H₆BNETPI, H₆BHEHPI, HMeIM, and the like.

When the step ST73A1 is applied to the step ST7 shown in FIG. 8B, the MOF may be formed after surface treatment is performed on a partial region of the blocking insulating layer. The surface treatment may be performed on the vertical parts VP of the blocking insulating layer 121B as shown in FIG. 4B. In another embodiment, the MOF on the partial region of the blocking insulating layer may be selectively removed, after the MOF is formed. The MOF may be selectively removed from the vertical parts VP of the blocking insulating layer 121B as shown in FIG. 4B.

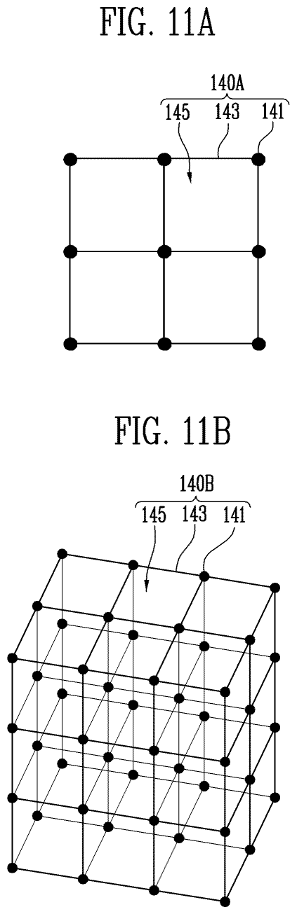

FIGS. 11A and 11B are views schematically illustrating an MOF.

Referring to FIGS. 11A and 11B, the MOF 140A or 140B is a porous compound formed through chemical bonding between a metal ion or metal cluster 141 and an organic ligand 143, and may have various structures according to properties. In particular, the MOF 140A or 140B may include pores 145 having a constant size and a constant arrangement. The size and arrangement of the pores 145 may be variously controlled according to properties of the MOF 140A or 140B. In an embodiment, the metal ion 141 of the MOF may include Zn²⁺, Zr⁴⁺, Al³⁺, and the like, the organic ligand 143 of the MOF may include 2-methylimidazole, 2-aminoterephthalic acid, 1,3,5-benzenetricarboxylate, and the like. The MOF may include MOF series, ZIF series, UIO series, SIM series, MIL series, HKUST series, and the like. In an embodiment, as shown in FIG. 11A, the MOF 140A may have a two-dimensional structure including pores 145 arranged two-dimensionally. In another embodiment, as shown in FIG. 11B, the MOF 140B may have a three-dimensional structure including pores 145 arranged three-dimensionally.

Referring to FIGS. 10A, 10B, 11A, and 11B, in the step ST73A3, the metal precursor may be infiltrated into the pores 145. In the step ST73A5, the nano-particles may be grown by using the metal precursor infiltrated into the pores 145 as a seed. The size of the nano-particles may be limited to be same as or smaller than that of the pores 145 of the MOF 140A or 140B, and be uniformly controlled.

In an embodiment, after the step ST73A3 shown in FIG. 10A, the step ST75 shown in FIG. 9A may be performed. Accordingly, the semiconductor memory device including the data storage layer having the structure shown in FIG. 7A may be provided.

In another embodiment, as shown in FIG. 10B, step ST73A7 of removing the organic ligand 143 of the MOF 140A or 140B shown in FIGS. 11A and 11B may be performed. The ST73A7 may be performed through annealing, and the metal ion or metal cluster 141 shown in FIGS. 11A and 11B may be absorbed into the nano-particles through the annealing.

In an embodiment, after the step ST73A7 is performed, the step ST75 shown in FIG. 9A may be performed. Accordingly, the nano-particles spaced apart from each other with a gap or insulating layer interposed therebetween may be provided.

In another embodiment, after the step ST73A7 is performed, the step ST74 shown in FIG. 9B may be performed.

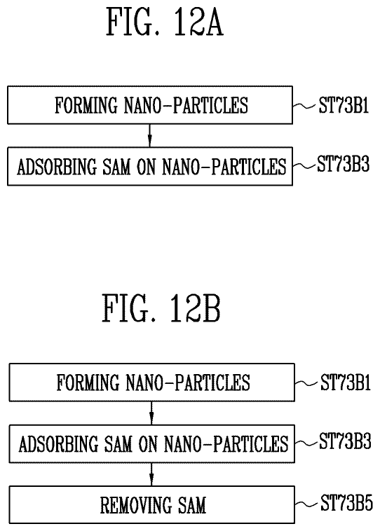

FIGS. 12A and 12B are flowcharts illustrating a manufacturing method of a memory layer using a Self-Assembled Monolayer (SAM). Processes shown in FIGS. 12A and 12B may be applied to the step ST73 shown in FIGS. 9A and 9B.

Referring to FIGS. 12A and 12B, the step ST73 may include step ST73B1 of forming nano-particles and step ST73B2 of adsorbing an SAM on the nano-particles.

In the step ST73B1, the nano-particles may be distributed on the blocking insulating layer formed in the step S71 shown in FIGS. 9A and 9B.

In an embodiment, when the step ST73B1 is applied to the step ST7 shown in FIG. 8B, the nano-particles may be formed after a surface treatment is performed on a partial region of the blocking insulating layer. In another embodiment, after the nano-particles are formed, nano-particles on a partial region of the blocking insulating layer may be selectively removed. The surface treatment may be performed from the vertical parts VP of the blocking insulating layer 121B as shown in FIG. 4B. The nano-particles may be selectively removed on the vertical parts VP of the blocking insulating layer 121B as shown in FIG. 4B.

The distance between the nano-particles may be equally controlled by the SAM adsorbed in step ST73B3.

In an embodiment, after the step ST73B3 shown in FIG. 12A, the step ST75 shown in FIG. 9A may be performed. Accordingly, the semiconductor memory device including the data storage layer having the structure shown in FIG. 7B may be provided.

In another embodiment, as shown in FIG. 12B, step ST73B5 of removing the SAM as an organic material may be performed. The step ST73B5 may be performed through annealing.

In an embodiment, after the step ST73B5 is performed, the step ST75 shown in FIG. 9A may be performed. Accordingly, the nano-particles spaced apart from each other with a gap or insulating layer interposed therebetween may be provided.

In another embodiment, after the step ST73B5 is performed, the step ST74 shown in FIG. 9B may be performed.

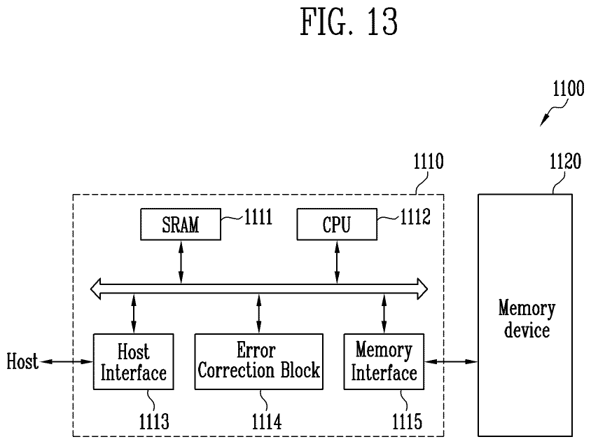

FIG. 13 is a block diagram illustrating a configuration of a memory system in accordance with an embodiment of the present disclosure.

Referring to FIG. 13, a memory system 1100 includes a memory device 1120 and a memory controller 1110.

The memory device 1120 may be a multi-chip package configured with a plurality of flash memory chips. The memory device 1120 may be a two-dimensional NAND flash memory device or a three-dimensional NAND flash memory device. The memory device 1120 may have a memory cell including nano-particles spaced apart from each other by a porous structure, a chemical chain, a gap, or an insulating layer.

The memory controller 1110 may control the memory device 1120, and may include Static Random Access Memory (SRAM) 1111, a Central Processing Unit (CPU) 1112, a host interface 1113, an error correction block 1114, and a memory interface 1115. The SRAM 1111 is used as operation memory of the CPU 1112, the CPU 1112 performs overall control operations for data exchange of the memory controller 1110, and the host interface 1113 may be provided with a data exchange protocol of a host connected with the memory system 1100. The error correction block 1114 may detect errors included in a data read from the memory device 1120, and may correct the detected errors. The memory interface 1115 interfaces with the memory device 1120. The memory controller 1110 may further include Read Only Memory (ROM) for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicate with the external device (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

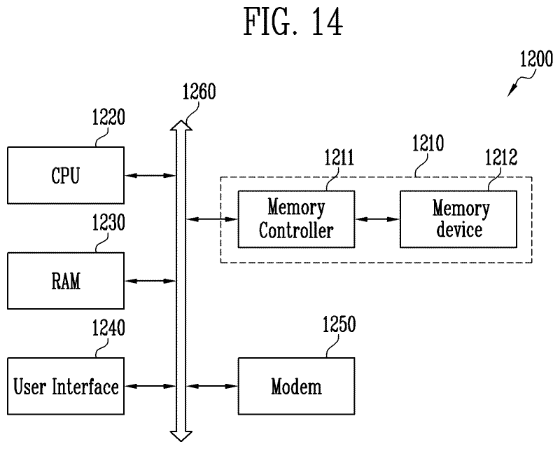

FIG. 14 is a block diagram illustrating a configuration of a computing system in accordance with an embodiment of the present disclosure.

Referring to FIG. 14, a computing system 1200 may include a CPU 1220, random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, mobile DRAM, and the like may be further included.

The memory system 1210 may be configured with a memory device 1212 and a memory controller 1211.

The memory device 1212 may be a two-dimensional NAND flash memory device or a three-dimensional NAND flash memory device. The memory device 1212 may have a memory cell including nano-particles spaced apart from each other by a porous structure, a chemical chain, a gap, or an insulating layer.

In accordance with some embodiments of the present disclosure, a data storage layer may include nano-particles.

In accordance with some embodiments of the present disclosure, cell characteristics of a semiconductor memory device may be uniform by uniformly controlling the distance between nano-particles. Accordingly, the operational reliability of the semiconductor memory device may be improved.

In accordance with some embodiments of the present disclosure, a floating gate isolated for each cell may be formed by aggregating uniformly distributed nano-particles. Accordingly, the operational reliability of the semiconductor memory device may be improved.

What is claimed is:

1. A method of manufacturing a semiconductor memory device, the method comprising:
forming a stack structure including first material layers and second material layers, which are alternately stacked;
forming a hole penetrating the stack structure;
forming a blocking insulating layer on a sidewall of the hole;
forming a data storage layer having nano-particles spaced apart from each other on the blocking insulating layer;
forming a tunnel insulating layer on the data storage layer; and
forming a channel layer on the tunnel insulating layer.

2. The method of claim 1, further comprising forming a recess region between the first material layers by etching a portion of each of the second material layers through the hole, before the blocking insulating layer is formed,
wherein the blocking insulating layer is formed to have an uneven surface along surfaces of the recess region and the hole.

3. The method of claim 2, wherein the data storage layer is disposed in a groove of the blocking insulating layer defined at each level where the second material layers are disposed, and
wherein the tunnel insulating layer is in contact with the blocking insulating layer at each level where the first material layers are disposed.

4. The method of claim 3, further comprising aggregating the nano-particles.

5. The method of claim 4, wherein the forming the data storage layer comprises:
forming a Metal Organic Framework (MOF) on the blocking insulating layer;
infiltrating a metal precursor into pores of the MOF; and
growing the nano-particles in the pores.

6. The method of claim 5, further comprising removing an organic ligand of the MOF after growing the nano-particles.

7. The method of claim 4, wherein the forming the data storage layer includes:
forming the nano-particles on the blocking insulating layer; and
adjusting a distance between the nano-particles by adsorbing a Self-Assembled Monolayer (SAM) on the nano-particles.

8. The method of claim 7, further comprising removing the SAM after adjusting the distance between the nano-particles.

9. A method of manufacturing a semiconductor memory device, the method comprising:
forming a stack structure including first material layers and second material layers, which are alternately stacked;
forming a hole penetrating the stack structure;
forming a blocking insulating layer on a sidewall of the hole;
forming a data storage layer having nano-particles spaced apart from each other on the blocking insulating layer;
forming a tunnel insulating layer on the data storage layer; and
forming a channel layer on the tunnel insulating layer,
wherein the forming the data storage layer comprises:
forming a Metal Organic Framework (MOF) on the blocking insulating layer;
infiltrating a metal precursor into pores of the MOF; and
growing the nano-particles in the pores.

10. The method of claim 9, further comprising removing an organic ligand of the MOF after growing the nano-particles.

11. The method of claim 9, further comprising forming a recess region between the first material layers by etching a portion of each of the second material layers through the hole, before the blocking insulating layer is formed,
wherein the blocking insulating layer is formed to have an uneven surface along surfaces of the recess region and the hole.

12. The method of claim 11, wherein the data storage layer is disposed in a groove of the blocking insulating layer defined at each level where each of the second material layers is disposed, and
wherein the tunnel insulating layer is in contact with the blocking insulating layer at each level where each of the first material layers is disposed.

13. The method of claim 11, further comprising:
removing an organic ligand of the MOF after growing the nano-particles; and
aggregating the nano-particles in the recess region.

14. A method of manufacturing a semiconductor memory device, the method comprising:
forming a stack structure including first material layers and second material layers, which are alternately stacked;
forming a hole penetrating the stack structure;
forming a blocking insulating layer on a sidewall of the hole;
forming a data storage layer having nano-particles spaced apart from each other on the blocking insulating layer;
forming a tunnel insulating layer on the data storage layer; and
forming a channel layer on the tunnel insulating layer,
wherein the forming the data storage layer comprises:
forming the nano-particles on the blocking insulating layer; and
adjusting a distance between the nano-particles by adsorbing a Self-Assembled Monolayer (SAM) on the nano-particles.

15. The method of claim 14, further comprising removing the SAM after adjusting the distance between the nano-particles.

16. The method of claim 14, further comprising forming a recess region between the first material layers by etching a portion of each of the second material layers through the hole, before the blocking insulating layer is formed,
wherein the blocking insulating layer is formed to have an uneven surface along surfaces of the recess region and the hole.

17. The method of claim 16, wherein the data storage layer is disposed in a groove of the blocking insulating layer defined at each level where each of the second material layers is disposed, and
wherein the tunnel insulating layer is in contact with the blocking insulating layer at each level where each of the first material layers is disposed.

18. The method of claim 16, further comprising:
removing the SAM after adjusting the distance between the nano-particles; and
aggregating the nano-particles in the recess region.
